(19) United States
(12) Patent Application Publication
(10) Pub. No.: US 2025/0365930 A1
(43) Pub. Date: Nov. 27, 2025

(54) DYNAMIC RANDOM ACCESS MEMORY STRUCTURE

(71) Applicant: Powerchip Semiconductor Manufacturing Corporation, Hsinchu (TW)

(72) Inventors: Shou-Zen Chang, Hsinchu City (TW); Chun-Lin Lu, Hsinchu City (TW); Chien-Ting Ho, Hsinchu (TW)

(73) Assignee: Powerchip Semiconductor Manufacturing Corporation, Hsinchu (TW)

(21) Appl. No.: 18/749,554

(22) Filed: Jun. 20, 2024

(30) Foreign Application Priority Data
May 23, 2024 (TW) 113119025

(51) Int. Cl. H10B 12/00

(52) U.S. Cl. CPC H10B 12/315

(57) ABSTRACT

A dynamic random access memory structure including a substrate, a word line structure, a first doped region, a second doped region, a capacitor structure, a via, a first dielectric layer, and a bit line is provided. The substrate includes a first surface and a second surface opposite to each other. The word line structure is disposed adjacent to the first surface. The first doped region and the second doped region are located in the substrate and separated from each other. The capacitor structure is located on the first surface. The capacitor structure is electrically connected to the first doped region. The via is located in the substrate. The via is electrically connected to the second doped region. The first dielectric layer is located between the via and the substrate. The bit line is located on the second surface. The bit line is electrically connected to the via.

### CROSS-REFERENCE TO RELATED APPLICATION

This application claims the priority benefit of Taiwan application serial no. 113119025, filed on May 23, 2024. The entirety of the above-mentioned patent application is hereby incorporated by reference herein and made a part of this specification.

### BACKGROUND

### Technical Field

The disclosure relates to a memory structure, and in particular relates to a dynamic random access memory (DRAM) structure.

### Description of Related Art

A dynamic random access memory has been developed. The dynamic random access memory includes transistors and capacitors. In the dynamic random access memory, capacitors are used as storage nodes. However, how to further improve the design flexibility and electrical performance of dynamic random access memory has become the goal of continuous efforts.

### SUMMARY

A dynamic random access memory structure, which may have higher design flexibility and better electrical performance, is provided in the disclosure.

A dynamic random access memory structure is provided in the disclosure, in which the dynamic random access memory structure includes a substrate, a word line structure, a first doped region, a second doped region, a capacitor structure, a via, a first dielectric layer, and a bit line. The substrate includes a first surface and a second surface opposite to each other. The word line structure is disposed adjacent to the first surface. The first doped region and the second doped region are located in the substrate and separated from each other. The capacitor structure is located on the first surface. The capacitor structure is electrically connected to the first doped region. The via is located in the substrate. The via is electrically connected to the second doped region. The first dielectric layer is located between the via and the substrate. The bit line is located on the second surface. The bit line is electrically connected to the via.

According to an embodiment of the disclosure, in the dynamic random access memory structure, the word line structure may be located on the first surface of the substrate.

According to an embodiment of the disclosure, in the dynamic random access memory structure, the word line structure may be located in the substrate.

According to an embodiment of the disclosure, the dynamic random access memory structure may further include a hard mask layer. The hard mask layer is located in the substrate and located on the word line structure. The hard mask layer may be closer to the first surface than the word line structure.

According to an embodiment of the disclosure, in the dynamic random access memory structure, the word line structure may include a word line and a second dielectric layer. The second dielectric layer is located between the word line and the substrate.

According to an embodiment of the disclosure, in the dynamic random access memory structure, the first doped region and the second doped region may be located in the substrate on two sides of the word line structure.

According to an embodiment of the disclosure, in the dynamic random access memory structure, the first doped region and the second doped region may be located in the substrate on a same side of the word line structure.

According to an embodiment of the disclosure, in the dynamic random access memory structure, the first doped region may be closer to the first surface than the second doped region.

According to an embodiment of the disclosure, the dynamic random access memory structure may further include an interconnect structure. The interconnect structure is located between the capacitor structure and the first doped region. The interconnect structure is electrically connected to the capacitor structure and the first doped region.

According to an embodiment of the disclosure, in the dynamic random access memory structure, the capacitor structure may directly contact the first doped region.

According to an embodiment of the disclosure, in the dynamic random access memory structure, the capacitor structure may include a first electrode, a second electrode, and the second dielectric layer. The first electrode is electrically connected to the first doped region. The second electrode is located on the first electrode. The second dielectric layer is located between the first electrode and the second electrode.

According to an embodiment of the disclosure, the dynamic random access memory structure may further include an interconnect structure. The interconnect structure is located between the first electrode and the first doped region. The interconnect structure may be electrically connected to the first electrode and the first doped region.

According to an embodiment of the disclosure, in the dynamic random access memory structure, the first electrode may directly contact the first doped region.

According to an embodiment of the disclosure, in the dynamic random access memory structure, a cross-sectional shape of the first electrode may be a U shape.

According to an embodiment of the disclosure, in the dynamic random access memory structure, a cross-sectional shape of the first electrode may be a cylindrical shape.

According to an embodiment of the disclosure, in the dynamic random access memory structure, the via may penetrate the second doped region.

According to an embodiment of the disclosure, in the dynamic random access memory structure, the via may not penetrate the second doped region.

According to an embodiment of the disclosure, in the dynamic random access memory structure, the via may be a through-substrate via (TSV).

According to an embodiment of the disclosure, the dynamic random access memory structure may further include a second dielectric layer. The second dielectric layer is located between the bit line and the second surface.

According to an embodiment of the disclosure, in the dynamic random access memory structure, the via may penetrate the second dielectric layer.

Based on the above, in the dynamic random access memory structure proposed by the disclosure, since the bit line is located on the second surface, the components on the first surface may be more flexible in design, so that the dynamic random access memory structure may have higher design flexibility. In addition, since the bit line is located on the second surface, the parasitic capacitance caused by the bit line may be greatly reduced. In addition, since the bit line is located on the second surface, the material of the bit line and the material of the dielectric layer between the bit lines (e.g., low dielectric constant material or air gap) may be flexibly selected, thereby reducing the resistance of the bit line and reducing the parasitic capacitance between the bit lines. In this way, the electrical performance of the dynamic random access memory structure may be improved.

In order to make the above-mentioned features and advantages of the disclosure comprehensible, embodiments accompanied with drawings are described in detail below.

### BRIEF DESCRIPTION OF THE DRAWINGS

FIG. 1 is a cross-sectional diagram of a dynamic random access memory structure according to some embodiments of the disclosure.

FIG. 2 is a cross-sectional diagram of a dynamic random access memory structure according to other embodiments of the disclosure.

FIG. 3 is a cross-sectional diagram of a dynamic random access memory structure according to other embodiments of the disclosure.

FIG. 4 is a cross-sectional diagram of a dynamic random access memory structure according to other embodiments of the disclosure.

FIG. 5 is a cross-sectional diagram of a dynamic random access memory structure according to other embodiments of the disclosure.

FIG. 6 is a cross-sectional diagram of a dynamic random access memory structure according to other embodiments of the disclosure.

### DETAILED DESCRIPTION OF DISCLOSED EMBODIMENTS

The following examples are described in detail with the accompanying drawings, but the provided examples are not intended to limit the scope of the disclosure. In order to facilitate understanding, the same components in the following description are described with the same symbols. In addition, the drawings are for illustrative purposes only and are not drawn in full scale. In fact, the dimensions of the various features may be arbitrarily increased or reduced for clarity of discussion.

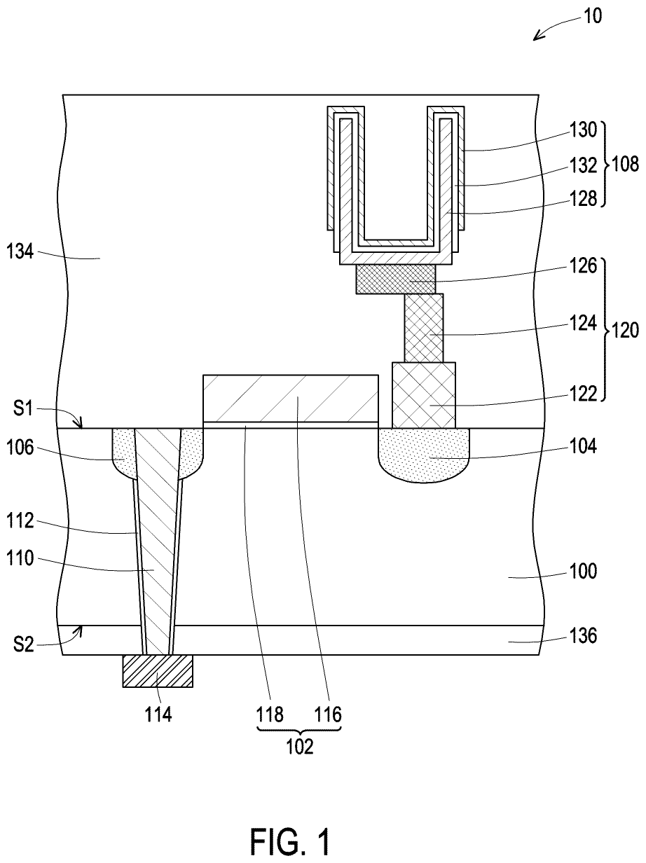

FIG. 1 is a cross-sectional diagram of a dynamic random access memory structure according to some embodiments of the disclosure.

Referring to FIG. 1, the dynamic random access memory structure 10 includes a substrate 100, a word line structure 102, a doped region 104, a doped region 106, a capacitor structure 108, a via 110, a dielectric layer 112, and a bit line 114. The substrate 100 includes a first surface S1 and a second surface S2 opposite to each other. In some embodiments, the first surface S1 may be the front surface of the substrate 100 and the second surface S2 may be the back surface of the substrate 100. In some embodiments, the substrate 100 may be a semiconductor substrate, such as a silicon substrate.

The word line structure 102 is disposed adjacent to the first surface S1. In this embodiment, the word line structure 102 may be located on the first surface S1 of the substrate 100, but the disclosure is not limited thereto. The word line structure 102 may include a word line 116 and a dielectric layer 118. In some embodiments, the material of the word line 116 is, for example, doped polysilicon, metal, or a combination thereof. The dielectric layer 118 is located between the word line 116 and the substrate 100. In some embodiments, the material of the dielectric layer 118 is, for example, silicon oxide.

The doped region 104 and the doped region 106 are located in the substrate 100 and separated from each other. The doped region 104 and the doped region 106 may respectively serve as either the source region or the drain region. In this embodiment, the doped region 104 and the doped region 106 may be located in the substrate 100 on two sides of the word line structure 102, but the disclosure is not limited thereto.

The capacitor structure 108 is located on the first surface S1. The capacitor structure 108 is electrically connected to the doped region 104. In some embodiments, the dynamic random access memory structure 10 may further include an interconnect structure 120. The interconnect structure 120 is located between the capacitor structure 108 and the doped region 104. The interconnect structure 120 may be electrically connected to the capacitor structure 108 and the doped region 104. In some embodiments, the interconnect structure 120 may include a contact 122, a contact window 124, and a pad 126, but the disclosure is not limited thereto. Those skilled in the art may adjust the components in the interconnect structure 120 according to requirements. The contact 122 is located on the doped region 104. The contact window 124 is located on the contact 122. The pad 126 is located between the capacitor structure 108 and the contact window 124. In some embodiments, the material of the interconnect structure 120 is, for example, tungsten, aluminum, copper, titanium, titanium nitride, tantalum, tantalum nitride, or a combination thereof.

The capacitor structure 108 may include the electrode 128, the electrode 130, and the dielectric layer 132. The electrode 128 is electrically connected to the doped region 104. The interconnect structure 120 is located between the electrode 128 and the doped region 104. The interconnect structure 120 is electrically connected to the electrode 128 and the doped region 104. In this embodiment, the cross-sectional shape of the electrode 128 may be a U shape, but the disclosure is not limited thereto. In some embodiments, the material of the electrode 128 is, for example, titanium nitride, silicon, or a combination thereof. The electrode 130 is located on the electrode 128. In some embodiments, the material of the electrode 130 is, for example, titanium nitride, silicon, germanium, tungsten, or a combination thereof. The dielectric layer 132 is located between the electrode 128 and the electrode 130. In some embodiments, the material of the dielectric layer 132 is, for example, a high-k material.

The via 110 is located in substrate 100. The via 110 is electrically connected to the doped region 106. In this embodiment, the via 110 may penetrate the doped region 106, but the disclosure is not limited thereto. As long as the via 110 is electrically connected to the doped region 106, the via 110 falls within the scope of the disclosure. In some embodiments, the via 110 may be a through-substrate via (TSV). In some embodiments, the material of the via 110 is, for example, copper, tungsten, titanium, titanium nitride, tantalum, tantalum nitride, cobalt, silicon, a composite thereof, or a combination thereof.

The dielectric layer 112 is located between the via 110 and the substrate 100. In some embodiments, the material of the dielectric layer 112 is, for example, silicon oxide.

The bit line 114 is located on the second surface S2. The bit line 114 is electrically connected to the via 110, so that the bit line 114 is electrically connected to the doped region 106. In some embodiments, the material of the bit line 114 is, for example, tungsten, aluminum, copper, titanium, titanium nitride, tantalum, tantalum nitride, cobalt, silicon, a composite thereof, or a combination thereof.

In some embodiments, the dynamic random access memory structure 10 may further include a dielectric layer 134. The dielectric layer 134 is located on the substrate 100, the word line structure 102, the capacitor structure 108, and the interconnect structure 120. In some embodiments, the dielectric layer 134 may be a multi-layer structure. In some embodiments, the material of the dielectric layer 134 is, for example, silicon oxide.

In some embodiments, the dynamic random access memory structure 10 may further include a dielectric layer 136. The dielectric layer 136 is located between the bit line 114 and the second surface S2. The via 110 may penetrate the dielectric layer 136 and be directly connected to the bit line 114. In other embodiments, the via 110 may be electrically connected to the bit line 114 through other vias (not shown). In some embodiments, the material of the bit line 114 is, for example, silicon oxide.

Based on the above embodiments, it may be seen that in the dynamic random access memory structure 10, since the bit line 114 is located on the second surface S2, the components on the first surface S1 may be more flexible in design, so that the dynamic random access memory structure 10 may have higher design flexibility. In addition, since the bit line 114 is located on the second surface S2, the material of the bit line 114 and the material of the dielectric layer (not shown) between the bit lines 114 (e.g., low dielectric constant material or air gap) may be flexibly selected, thereby reducing the resistance of the bit line 114 and reducing the parasitic capacitance between the bit lines 114. In this way, the electrical performance of the dynamic random access memory structure 10 may be improved.

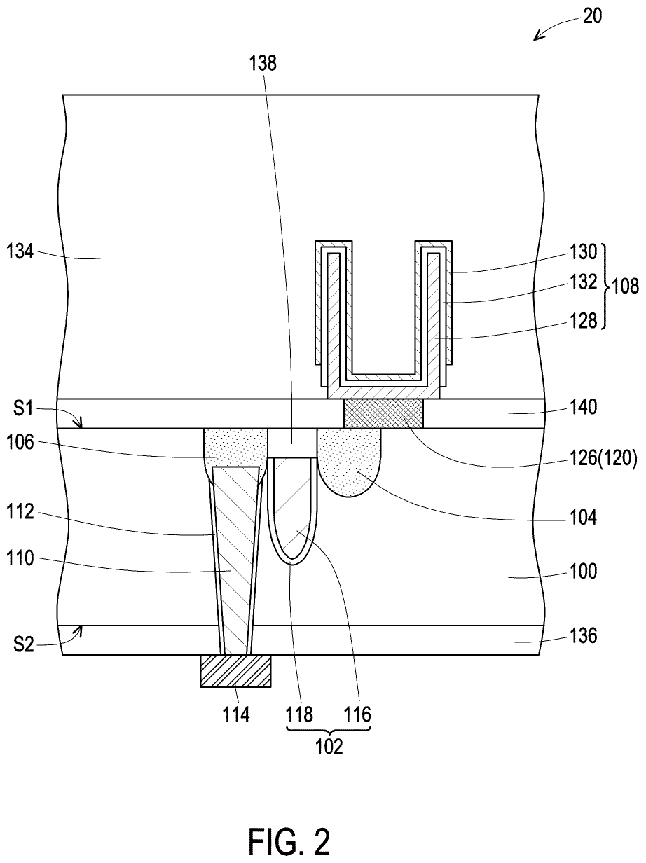

FIG. 2 is a cross-sectional diagram of a dynamic random access memory structure according to other embodiments of the disclosure.

Referring to FIG. 1 and FIG. 2, the differences between the dynamic random access memory structure 20 of FIG. 2 and the dynamic random access memory structure 10 of FIG. 1 are as follows. In the dynamic random access memory structure 20, the word line structure 102 may be located in the substrate 100. In the dynamic random access memory structure 20, the via 110 may not penetrate the doped region 106, but the disclosure is not limited thereto. As long as the via 110 is electrically connected to the doped region 106, the via 110 falls within the scope of the disclosure.

In addition, the dynamic random access memory structure 20 may further include a hard mask layer 138. The hard mask layer 138 is located in the substrate 100 and located on the word line structure 102. The hard mask layer 138 may be closer to the first surface S1 than the word line structure 102. In some embodiments, the material of the hard mask layer 138 is, for example, silicon nitride. In the dynamic random access memory structure 20, the interconnect structure 120 may not include the contact 122 and the contact window 124, but the disclosure is not limited thereto. Those skilled in the art may adjust the components in the interconnect structure 120 according to requirements. In addition, the dynamic random access memory structure 20 may further include a dielectric layer 140. The dielectric layer 140 is located between the dielectric layer 134 and the substrate 100. The pad 126 may be located in the dielectric layer 140. In some embodiments, the material of the dielectric layer 140 is, for example, silicon oxide, silicon nitride, silicon carbonitride, or a combination thereof. In addition, in FIG. 1 and FIG. 2, the same or similar components are denoted by the same reference numerals, and descriptions thereof are omitted.

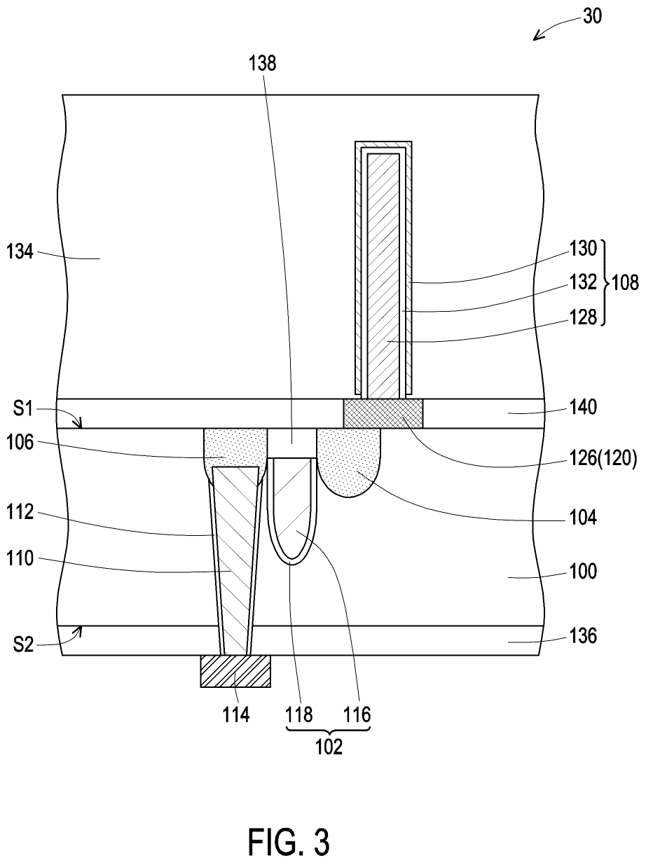

FIG. 3 is a cross-sectional diagram of a dynamic random access memory structure according to other embodiments of the disclosure.

Referring to FIG. 2 and FIG. 3, the differences between the dynamic random access memory structure 30 of FIG. 3 and the dynamic random access memory structure 20 of FIG. 2 are as follows. In the dynamic random access memory structure 30, the cross-sectional shape of the electrode 128 may be a cylindrical shape. In addition, in FIG. 2 and FIG. 3, the same or similar components are denoted by the same reference numerals, and descriptions thereof are omitted.

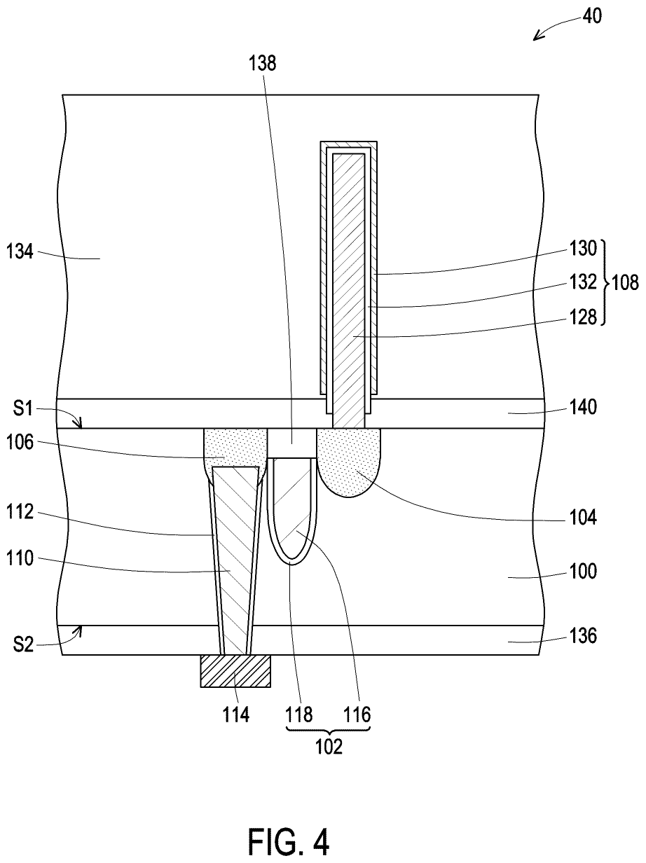

FIG. 4 is a cross-sectional diagram of a dynamic random access memory structure according to other embodiments of the disclosure.

Referring to FIG. 3 and FIG. 4, the differences between the dynamic random access memory structure 40 of FIG. 4 and the dynamic random access memory structure 30 of FIG. 3 are as follows. The dynamic random access memory structure 40 may not include the interconnect structure 120 in FIG. 3. That is, the capacitor structure 108 may directly contact the doped region 104. For example, the electrode 128 may directly contact the doped region 104. In addition, in FIG. 3 and FIG. 4, the same or similar components are denoted by the same reference numerals, and descriptions thereof are omitted.

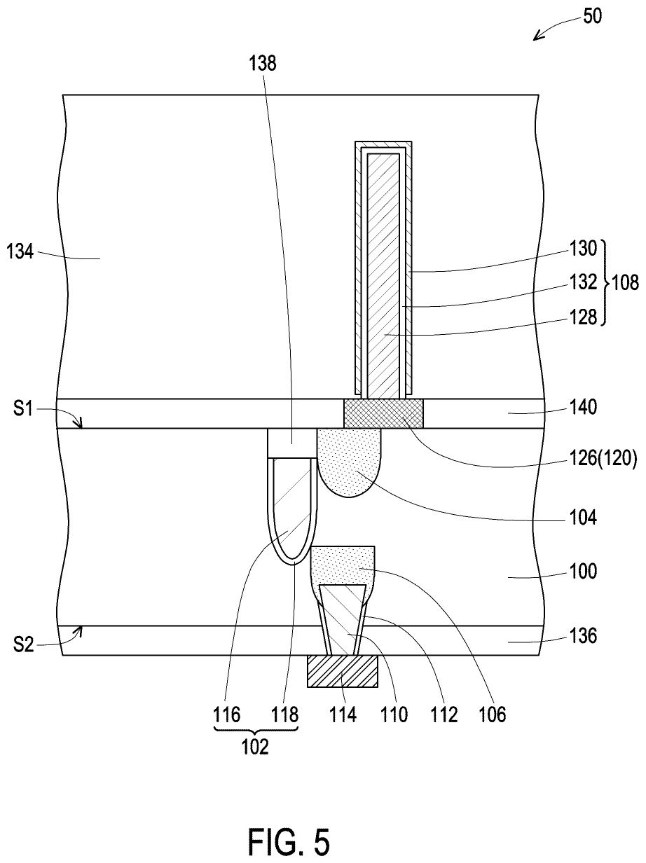

FIG. 5 is a cross-sectional diagram of a dynamic random access memory structure according to other embodiments of the disclosure.

Referring to FIG. 3 and FIG. 5, the differences between the dynamic random access memory structure 50 of FIG. 5 and the dynamic random access memory structure 30 of FIG. 3 are as follows. In the dynamic random access memory structure 50, the doped region 104 and the doped region 106 may be located in the substrate 100 on the same side of the word line structure 102. The doped region 104 may be closer to the first surface S1 than the doped region 106. Therefore, the area of the dynamic random access memory structure 50 may be effectively reduced. In some embodiments, if half of the minimum spacing between components is set to F, the dynamic random access memory structure 50 may be applied to a layout with a memory cell bit size of 4F2. In addition, in FIG. 3 and FIG. 5, the same or similar components are denoted by the same reference numerals, and descriptions thereof are omitted.

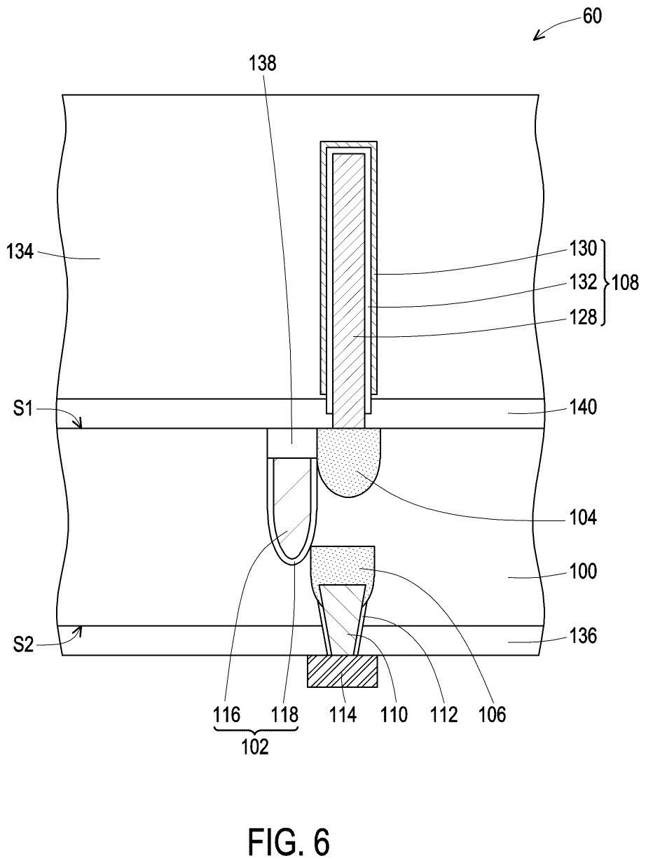

FIG. 6 is a cross-sectional diagram of a dynamic random access memory structure according to other embodiments of the disclosure.

Referring to FIG. 5 and FIG. 6, the differences between the dynamic random access memory structure 60 of FIG. 6 and the dynamic random access memory structure 50 of FIG. 5 are as follows. The dynamic random access memory structure 60 may not include the interconnect structure 120 in FIG. 5. That is, the capacitor structure 108 may directly contact the doped region 104. For example, the electrode 128 may directly contact the doped region 104. In addition, in FIG. 5 and FIG. 6, the same or similar components are denoted by the same reference numerals, and descriptions thereof are omitted.

To sum up, in the dynamic random access memory structure of the above embodiments, the substrate includes a first surface and a second surface opposite to each other. The capacitor structure is located on the first surface and the bit line is located on the second surface. Since the bit line is located on the second surface, the components on the first surface may be more flexible in design, so that the dynamic random access memory structure may have higher design flexibility. In addition, since the bit line is located on the second surface, the parasitic capacitance caused by the bit line may be greatly reduced. In addition, since the bit line is located on the second surface, the material of the bit line and the material of the dielectric layer between the bit lines (e.g., low dielectric constant material or air gap) may be flexibly selected, thereby reducing the resistance of the bit line and reducing the parasitic capacitance between the bit lines. In this way, the electrical performance of the dynamic random access memory structure may be improved.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A dynamic random access memory structure, comprising:
a substrate, comprising a first surface and a second surface opposite to each other;
a word line structure, disposed adjacent to the first surface;
a first doped region and a second doped region, located in the substrate and separated from each other;
a capacitor structure, located on the first surface and electrically connected to the first doped region;
a via, located in the substrate and electrically connected to the second doped region;
a first dielectric layer, located between the via and the substrate; and
a bit line, located on the second surface and electrically connected to the via.

2. The dynamic random access memory structure according to claim 1, wherein the word line structure is located on the first surface of the substrate.

3. The dynamic random access memory structure according to claim 1, wherein the word line structure is located in the substrate.

4. The dynamic random access memory structure according to claim 3, further comprising:
a hard mask layer, located in the substrate and located on the word line structure, wherein the hard mask layer is closer to the first surface than the word line structure.

5. The dynamic random access memory structure according to claim 1, wherein the word line structure comprises:
a word line; and
a second dielectric layer, located between the word line and the substrate.

6. The dynamic random access memory structure according to claim 1, wherein the first doped region and the second doped region are located in the substrate on two sides of the word line structure.

7. The dynamic random access memory structure according to claim 1, wherein the first doped region and the second doped region are located in the substrate on a same side of the word line structure.

8. The dynamic random access memory structure according to claim 7, wherein the first doped region is closer to the first surface than the second doped region.

9. The dynamic random access memory structure according to claim 1, further comprising:
an interconnect structure, located between the capacitor structure and the first doped region and electrically connected to the capacitor structure and the first doped region.

10. The dynamic random access memory structure according to claim 1, wherein the capacitor structure directly contacts the first doped region.

11. The dynamic random access memory structure according to claim 1, wherein the capacitor structure comprises:
a first electrode, electrically connected to the first doped region;
a second electrode, located on the first electrode; and
the second dielectric layer, located between the first electrode and the second electrode.

12. The dynamic random access memory structure according to claim 11, further comprising:
an interconnect structure, located between the first electrode and the first doped region and electrically connected to the first electrode and the first doped region.

13. The dynamic random access memory structure according to claim 11, wherein the first electrode directly contacts the first doped region.

14. The dynamic random access memory structure according to claim 11, wherein a cross-sectional shape of the first electrode comprises a U-shape.

15. The dynamic random access memory structure according to claim 11, wherein a cross-sectional shape of the first electrode comprises a cylindrical shape.

16. The dynamic random access memory structure according to claim 1, wherein the via penetrates the second doped region.

17. The dynamic random access memory structure according to claim 1, wherein the via does not penetrate the second doped region.

18. The dynamic random access memory structure according to claim 1, wherein the via comprises a through-substrate via.

19. The dynamic random access memory structure according to claim 1, further comprising:
a second dielectric layer, located between the bit line and the second surface.

20. The dynamic random access memory structure according to claim 19, wherein the via penetrates the second dielectric layer.
